(19) United States
(12) Patent Application Publication
(10) Pub. No.: US 2019/0123072 A1
(43) Pub. Date: Apr. 25, 2019

(54) DISPLAY PANEL AND PIXEL CIRCUIT THEREOF

(71) Applicant: Chunghwa Picture Tubes, LTD., Taoyuan City (TW)

(72) Inventors: Wei-Lung Li, Taoyuan City (TW); Yan-Wun You, Changhua County (TW); Wei-Feng Jang, Changhua County (TW)

(73) Assignee: Chunghwa Picture Tubes, LTD., Taoyuan City (TW)

(21) Appl. No.: 15/835,463

(22) Filed: Dec. 8, 2017

(30) Foreign Application Priority Data
Oct. 25, 2017 (CN) 201721382534.0

(51) Int. Cl. H01L 27/12; G02F 1/1368; G02F 1/167; G02F 1/1362

(52) U.S. Cl. CPC H01L 27/1255; G02F 1/1368; G09G 3/3648; G02F 1/136286; G02F 1/167

(57) ABSTRACT

A display panel and a pixel circuit thereof are provided. The pixel circuit includes a first transistor, a second transistor, a capacitor, a storage capacitor and a pixel capacitor. A first terminal of the first transistor is coupled to a source line, and a control terminal thereof is coupled to a gate line. A first terminal of the second transistor is coupled to a second terminal of the first transistor, and a control terminal of the second transistor is coupled to the gate line. A first terminal of the capacitor is coupled to the second terminal of the first transistor, and a second terminal of the capacitor receives a common voltage. The storage capacitor is coupled in series between a second terminal of the second transistor and the common voltage. The pixel capacitor is coupled in series between the second terminal of the second transistor and the common voltage.

### CROSS-REFERENCE TO RELATED APPLICATION

This application claims the priority benefit of China application serial no. 201721382534.0, filed on Oct. 25, 2017. The entirety of the above-mentioned patent application is hereby incorporated by reference herein and made a part of this specification.

### BACKGROUND OF THE INVENTION

### Field of the Invention

The invention relates to a pixel circuit, and particularly relates to a display panel and a pixel circuit thereof.

### Description of Related Art

Along with progress of electronic technology, electronic devices have become indispensable tools in people's daily life. To provide a high quality display interface is an important function of today's electronic device.

Under the existing pixel circuit architecture, in a voltage keeping period, a pixel voltage stored in a pixel capacitor probably has a leakage phenomenon, such that a display intensity presented by the pixel is distorted. Moreover, in the conventional pixel circuit, during a charging process of the pixel capacitor, the voltage on the pixel capacitor may have an instantaneous drop phenomenon (i.e. a feed through voltage phenomenon) due to a turning-off operation of a thin-film transistor, which causes reduction of the display quality.

### SUMMARY OF THE INVENTION

The invention provides a display panel and a pixel circuit thereof. The pixel circuit includes a first transistor, a second transistor, a capacitor, a storage capacitor and a pixel capacitor. A first terminal of the first transistor is coupled to a source line, and a control terminal thereof is coupled to a gate line. A first terminal of the second transistor is coupled to a second terminal of the first transistor, and a control terminal of the second transistor is coupled to the gate line. A first terminal of the capacitor is coupled to the second terminal of the first transistor, and a second terminal of the capacitor receives a common voltage. The storage capacitor is coupled in series between a second terminal of the second transistor and the common voltage. The pixel capacitor is coupled in series between the second terminal of the second transistor and the common voltage.

In an embodiment of the invention, a capacitance of the capacitor is greater than capacitances of the storage capacitor and the pixel capacitor.

In an embodiment of the invention, a capacitance of the capacitor is not greater than capacitances of the storage capacitor and the pixel capacitor.

In an embodiment of the invention, types of the first transistor and the second transistor are the same.

In an embodiment of the invention, the first transistor and the second transistor are all N-type thin-film transistors.

In an embodiment of the invention, a first electrode plate of the capacitor, the second terminal of the first transistor and the first terminal of the second transistor share a same metal layer.

In an embodiment of the invention, the capacitor is a metal-insulator-metal capacitor.

In an embodiment of the invention, the capacitor is configured to maintain a voltage on the second terminal of the first transistor and the first terminal of the second transistor during a voltage keeping period of the pixel circuit.

In an embodiment of the invention, the common voltage is a direct current voltage.

In an embodiment of the invention, the display panel is an electrophoretic display panel or a liquid crystal display panel.

The invention provides a display panel including a plurality of gate lines, a plurality of source lines and a plurality of the aforementioned pixel circuits.

In an embodiment of the invention, a capacitance of the capacitor is greater than capacitances of the storage capacitor and the pixel capacitor.

In an embodiment of the invention, a capacitance of the capacitor is not greater than capacitances of the storage capacitor and the pixel capacitor.

In an embodiment of the invention, a first electrode plate of the capacitor, the second terminal of the first transistor, and the first terminal of the second transistor share a same metal layer.

In an embodiment of the invention, the capacitor is configured to maintain a voltage on the second terminal of the first transistor and the first terminal of the second transistor during a voltage keeping period of the pixel circuit.

According to the above description, in the pixel circuit of the invention, by configuring a capacitor between the common voltage and a connection point of the first transistor and the second transistor, a variation amount of a voltage level on the connection point of the first transistor and the second transistor is maintained on the one hand, and on the other hand, a leakage phenomenon of charges of the pixel capacitor is prevented, and an influence of a feed through voltage on a pixel voltage is decreased, so as to maintain the display quality.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a pixel circuit according to an embodiment of the invention.

FIG. 2 is a schematic diagram of a structure of a capacitor of the pixel circuit according to an embodiment of the invention.

FIG. 3 is an operation waveform diagram of the pixel circuit according to an embodiment of the invention.

FIG. 4 is a schematic diagram of a display panel according to an embodiment of the invention.

### DESCRIPTION OF EMBODIMENTS

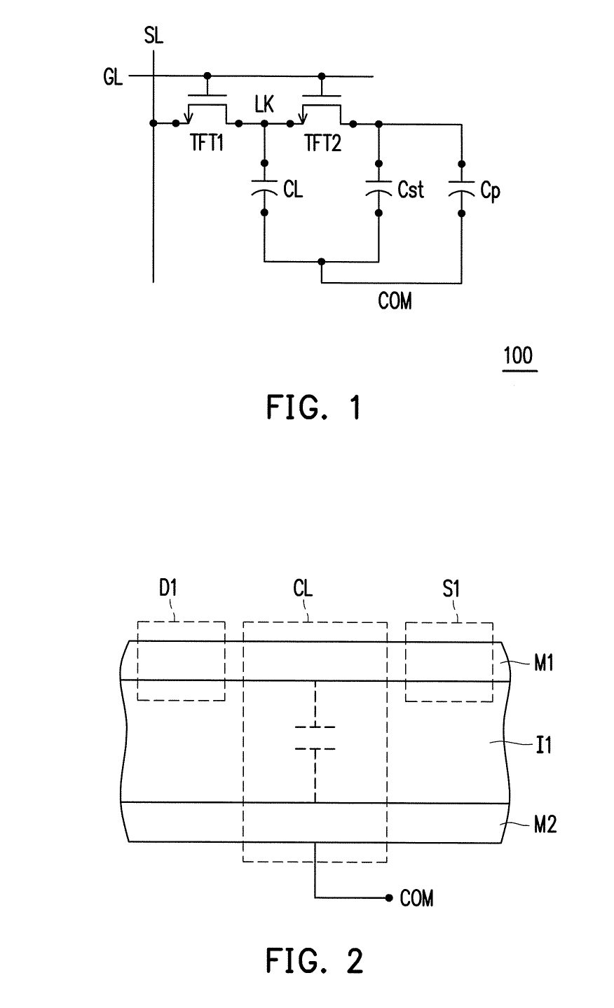

Referring to FIG. 1, FIG. 1 is a schematic diagram of a pixel circuit according to an embodiment of the invention. The pixel circuit 100 includes transistors TFT1, TFT2, a capacitor CL, a storage capacitor Cst and a pixel capacitor Cp. A first terminal of the transistor TFT1 is coupled to a source line SL, a control terminal thereof is coupled to a gate line GL, and a second terminal of the transistor TFT1 is coupled to a node LK, and is coupled to a first terminal of the transistor TFT2 through the node LK. A control terminal of the transistor TFT2 is coupled to the gate line GL, and a second terminal thereof is coupled to the storage capacitor Cst and the pixel capacitor Cp. Moreover, a first end of the capacitor CL is coupled to the node LK, and another end of the capacitor CL receives a common voltage COM. The storage capacitor Cst and the pixel capacitor Cp are coupled in parallel, and are coupled between the second terminal of the transistor TFT2 and the common voltage COM.

In view of operations, the pixel circuit 100 may transmit a gate driving signal through the gate line GL to turn on the transistors TFT1, TFT2 during a data writing period. Moreover, source data is transmitted through the source line SL, and is transmitted to the storage capacitor Cst and the pixel capacitor Cp through the turned-on transistors TFT1, TFT2. In this way, the source data may be written into the storage capacitor Cst and the pixel capacitor Cp. It should be noted that in the mean time, the source data may be written into the capacitor CL through the turned-on transistor TFT1, in this way, a difference of voltage levels between the first terminal and the second terminal of the transistor TFT2 may be close to 0 volt.

After the data writing period is ended, the pixel circuit 100 enters a data keeping period, and now the transistors TFT1, TFT2 are turned off in response to the disabled gate driving signal transmitted by the gate line GL. Based on the charges stored in the capacitor CL, a level on the node LK is maintained to be substantially equal to a level of the source data. Now, the level on the node LK is not smaller than a level on the pixel capacitor Cp, and is close to a level on the storage capacitor Cst and the pixel capacitor Cp (the second terminal of the transistor TFT2). Therefore, a path of leakage of the charges on the storage capacitor Cst and the pixel capacitor Cp through the transistors TFT1, TFT2 is blocked, and occurrence of the leakage phenomenon is mitigated.

It should be noted that in the present embodiment, the pixel circuit 100 constructs a longer current transmission path through the transistors TFT1, TFT2, such that when the transistors TFT1, TFT2 are turned off, the amount of leakage and the chance of leakage of the charges on the storage capacitor Cst and the pixel capacitor Cp generated through the transistors TFT1, TFT2 may be decreased. Moreover, the voltage level provided to the node LK by the capacitor CL may have a blocking effect, and the possibility of leakage of the charges on the storage capacitor Cst and the pixel capacitor Cp through the transistors TFT1, TFT2 is decreased.

On the other hand, in the present embodiment, when the pixel circuit 100 enters the data keeping period, at the moment that the transistors TFT1, TFT2 are turned off according to the gate driving signal, an amount of transient variation of the voltage level on the node LK caused by the feed through voltage phenomenon is also suppressed due to configuration of the capacitor CL. Namely, through a voltage stabilizing effect provided by the capacitor CL, the difference of the voltage levels between the first terminal and the second terminal of the transistor TFT2 may be maintained to a tiny value (which is close to 0 volt), and the possibility of leakage of the charges on the storage capacitor Cst and the pixel capacitor Cp is decreased.

It should be noted that in order to provide a better blocking effect, a capacitance of the capacitor CL may be greater than capacitances of the storage capacitor Cst and the pixel capacitor Cp. Alternatively, the capacitance of the capacitor CL may be not greater than the capacitances of the storage capacitor Cst and the pixel capacitor Cp. In a preferred embodiment, the capacitance of the capacitor CL is, for example, about 5 times of the capacitances of the storage capacitor Cst and the pixel capacitor Cp, though the invention is not limited thereto.

It should be noted that in the present embodiment, the transistors TFT1, TFT2 may be thin-film transistors of the same type, for example, N-type thin-film transistors. The common voltage COM may be a direct current (DC) voltage. Moreover, the pixel circuit 100 is adapted to a liquid crystal display panel or an electrophoretic display panel. The capacitor CL may have a metal-insulator-metal (MIM) structure.

Referring to FIG. 2, FIG. 2 is a schematic diagram of a structure of the capacitor of the pixel circuit according to an embodiment of the invention. The capacitor CL is formed by a metal layer M1, a dielectric layer I1 and a metal layer M2. An upper electrode of the capacitor CL may share a same metal layer M1 with a drain D1 of the transistor TFT1 and a source S1 of the transistor TFT2, and a lower electrode of the capacitor CL is formed by the metal layer M2, and is used for receiving the common voltage COM.

Under such structure, configuration of the capacitor CL may be completed without using an extra optical mask. Actually, the capacitor CL may be synchronously produced during a process of manufacturing the transistors TFT1, TFT2. The capacitor CL may be configured under the demand of using minimum optical masks, which doesn't increase the cost of production.

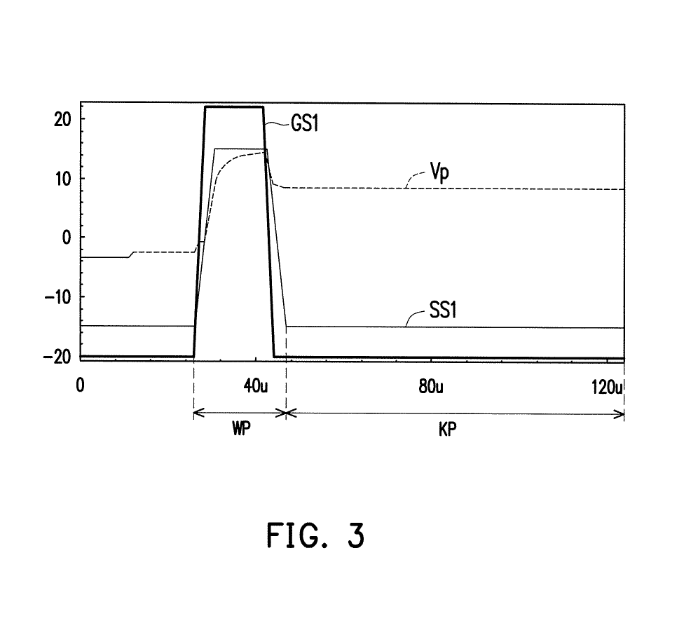

Referring to following FIG. 3, FIG. 3 is an operation waveform diagram of the pixel circuit according to an embodiment of the invention. During the data writing period WP, the gate driving signal GS1 is pulled high to turn on the transistors TFT1, TFT2, and the source data SS1 is written into the storage capacitor Cst and the pixel capacitor Cp through the transistors TFT1, TFT2, so that a pixel voltage Vp is pulled up. In the data keeping period KP after the data writing period WP, the pixel voltage Vp drops instantaneously, through a dropping degree of the pixel voltage Vp may be suppressed due to configuration of the capacitor CL. Moreover, in the data keeping period KP, the pixel voltage Vp is almost maintained to a fixed voltage level, and is not decreased due to the leakage.

Through software simulation, in FIG. 3, after the pixel circuit of the invention enters the data keeping period KP and maintains for 20 ms, the pixel voltage Vp drops from 8.6462 volts to 7.0846 volts, which only has a drop of 1.5616 volts. If the capacitor CL is removed, by performing the same software simulation, it is known that the pixel voltage Vp drops from 8.0255 volts to 5.8102 volts, which has a drop of 2.2153 volts. It is known that the dropping degree of the pixel voltage Vp is effectively suppressed through configuration of the capacitor CL.

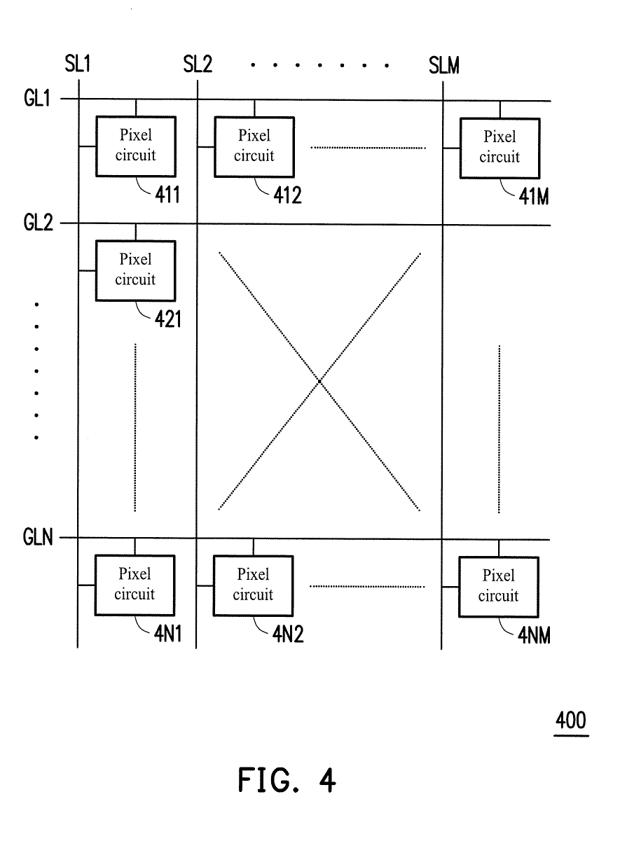

Referring to FIG. 4, FIG. 4 is a schematic diagram of a display panel according to an embodiment of the invention. The display panel 400 includes a plurality of gate lines GL1-GLN, a plurality of source lines SL1-SLM and a plurality of pixel circuits 411-4NM. Each of the pixel circuits 411-4NM is the same to the pixel circuit 100 shown in FIG. 1. By configuring the capacitor CL between the node LK and the common voltage COM in each of the pixel circuits 411-4NM to serve as a block capacitor, the leakage phenomenon of the storage capacitor Cst and the pixel capacitor Cp probably generated in the pixel circuits 411-4NM may be mitigated, and the influence of a feed through voltage on the voltage level of the storage capacitor Cst and the pixel capacitor Cp generated during the operation process may also be decreased, so as to maintain the display quality of the pixel circuits 411-4NM.

In summary, in the pixel circuit of the invention, a capacitor is configured on the connection point of the transistors TFT1-TFT2 coupled in series, and through a block function of such capacitor, the storage capacitor in the pixel circuit, the leakage phenomenon of the charges of the storage capacitor and the pixel capacitor in the pixel circuit may be effectively mitigated. Moreover, through the block function of the capacitor, the influence of the feed through voltage on the storage capacitor and the pixel capacitor is also decreased, so as to maintain the display quality of the pixel circuit.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A pixel circuit, adapted to a display panel, and comprising:
a first transistor, having a first terminal coupled to a source line, and a control terminal coupled to a gate line;
a second transistor, having a first terminal coupled to a second terminal of the first transistor, and a control terminal coupled to the gate line;
a capacitor, having a first terminal coupled to the second terminal of the first transistor, and a second terminal receiving a common voltage;
a storage capacitor, coupled in series between a second terminal of the second transistor and the common voltage; and
a pixel capacitor, coupled in series between the second terminal of the second transistor and the common voltage.

2. The pixel circuit as claimed in claim 1, wherein a capacitance of the capacitor is greater than capacitances of the storage capacitor and the pixel capacitor.

3. The pixel circuit as claimed in claim 1, wherein a capacitance of the capacitor is not greater than capacitances of the storage capacitor and the pixel capacitor.

4. The pixel circuit as claimed in claim 1, wherein types of the first transistor and the second transistor are the same.

5. The pixel circuit as claimed in claim 4, wherein the first transistor and the second transistor are all N-type thin-film transistors.

6. The pixel circuit as claimed in claim 1, wherein a first electrode plate of the capacitor, the second terminal of the first transistor and the first terminal of the second transistor share a same metal layer.

7. The pixel circuit as claimed in claim 1, wherein the capacitor is a metal-insulator-metal capacitor.

8. The pixel circuit as claimed in claim 1, wherein the capacitor is configured to maintain a voltage on the second terminal of the first transistor and the first terminal of the second transistor during a voltage keeping period of the pixel circuit.

9. The pixel circuit as claimed in claim 1, wherein the common voltage is a direct current voltage.

10. The pixel circuit as claimed in claim 1, wherein the display panel is an electrophoretic display panel or a liquid crystal display panel.

11. A display panel, comprising:
a plurality of gate lines;
a plurality of source lines; and
a plurality of the pixel circuits, respectively coupled to the gate lines and the source lines, and each of the pixel circuits comprising:
a first transistor, having a first terminal coupled to the corresponding source line, and a control terminal coupled to the corresponding gate line;
a second transistor, having a first terminal coupled to a second terminal of the first transistor, and a control terminal coupled to the corresponding gate line;
a capacitor, having a first terminal coupled to the second terminal of the first transistor, and a second terminal receiving a common voltage;
a storage capacitor, coupled in series between a second terminal of the second transistor and the common voltage; and
a pixel capacitor, coupled in series between the second terminal of the second transistor and the common voltage.

12. The display panel as claimed in claim 11, wherein a capacitance of the capacitor is greater than capacitances of the storage capacitor and the pixel capacitor.

13. The display panel as claimed in claim 11, wherein a capacitance of the capacitor is not greater than capacitances of the storage capacitor and the pixel capacitor.

14. The display panel as claimed in claim 11, wherein a first electrode plate of the capacitor, the second terminal of the first transistor, and the first terminal of the second transistor share a same metal layer.

15. The display panel as claimed in claim 11, wherein the capacitor is configured to maintain a voltage on the second terminal of the first transistor and the first terminal of the second transistor during a voltage keeping period of the pixel circuit.
